(19) United States
(12) Patent Application Publication
(10) Pub. No.: US 2020/0052150 A1
(43) Pub. Date: Feb. 13, 2020

(54) PROCESSING APPARATUS AND PROCESSING METHOD

(71) Applicant: FLOSFIA INC., Kyoto (JP)

(72) Inventors: Shingo YAGYU, Kyoto (JP); Toshimi HITORA, Kyoto (JP)

(21) Appl. No.: 16/499,457

(22) PCT Filed: Mar. 29, 2018
(86) PCT No.: PCT/JP2018/013444

§ 371 Date: Sep. 30, 2019

(30) Foreign Application Priority Data
Mar. 31, 2017 (JP) 2017-073294
Mar. 31, 2017 (JP) 2017-073295

(51) Int. Cl. H01L 31/18; H01L 31/0392; H01L 31/046

(52) U.S. Cl. CPC H01L 31/1876; H01L 31/046; H01L 31/03926

(57) ABSTRACT

A processing system and a processing method are provided that allows for convenient and easy, roll-to-roll processing of both sides of a substrate at atmospheric pressure. A system of processing a substrate using mist or droplets containing a processing agent, wherein the mist or droplets is allowed to be retained and the substrate is processed by impregnating with the retained mist or droplets using a processing device including a retaining section that retains the mist or droplets and an impregnation section that impregnates the substrate with the mist or droplets.

### TECHNICAL FIELD

The present invention relates to a processing apparatus and a processing method that is useful for deposition and etching.

### BACK GROUND ART

A vacuum apparatus is used for deposition and etching in a manufacturing process of a semiconductor. As such a vacuum apparatus, Patent Literature 1 discloses a vacuum processing apparatus including a plurality of processing chambers. Such a vacuum processing apparatus includes, for example, a conveying means inside thereof, and is configured to convey a substrate under a vacuum atmosphere. However, when a deposition process or an etching process is performed in such a single wafer type processing chamber, for example, the processing result including a film quality in the deposition process or a film quality in the etching process tends to depend on an environment in a processing chamber at the beginning of the process. Further, in the processing chamber which was in an idling state (standby state) for a long time before the beginning of the processing, there has been a problem that is difficult to obtain a desired processing results of several substrates from the beginning of the processing. In order to solve such a problem, it has been necessary to introduce a non-product substrates (dummy substrates) into the processing chamber prior to the processing product substrates. In addition, it was necessary to introduce a product substrate after the environment in the processing chamber was stabilized. In addition, the amount of dummy substrates introduced into the processing depends on an environment in the processing chamber and a period of time during which the dummy substrates are in an idle state (standby state).

Also, while a Si substrate had been used in a manufacture or the like of solar cells, a silicon thin-film solar cell using a silicon thin film has recently been studied. The silicon thin-film solar cell, that includes only a small amount of silicon, is expected to be low in cost. In particular, a method of forming the silicon thin-film solar cell by roll-to-roll processing using a long flexible substrate is highly expected to be low in cost. However, in the case of using a flexible substrate, depending on a degree of parallelism with, an electrode or the like, there is a problem that an in-plane distribution occurs in the processing result (for example, a film quality and thickness of obtained films in case of a deposition process and an etching amount in case of an etching process) of the flexible substrate. In order to cope with such a problem, a method of using a pressing member as described in Patent Literature 2 has been proposed. However, the method described therein is not always satisfactory due to a friction generated by pressing or dirt and the like adhered to the flexible substrate. Further, there has been a problem of the vacuum processing apparatus as described above. Therefore, a processing apparatus and a processing method that enables to perform a simple and easy surface treatment of good quality and is applicable to a roll-to-roll process without the above-mentioned problem of a vacuum treatment apparatus have been desired.

### PRIOR ART DOCUMENT

### Patent Literature

Patent Literature 1: JP2012-119626A

Patent Literature 2: JP2010-070816A

### SUMMARY OF INVENTION

### Technical Problem

An object of the present inventive subject matter is to provide a processing apparatus and a processing method that is capable of processing a base industrially advantageously.

### Solution to Problem

As a result of earnest examination to achieve the above object, the inventors found that when mist or droplets containing a raw material for deposition is retained and impregnated into a substrate, a film of good quality can be obtained simply and easily on both sides of the substrate. Furthermore, the inventors found that such a processing apparatus can be applied to a surface processing, such as etching, and found that the processing apparatus can solve the above-mentioned conventional problem.

In addition, as a result of earnest examination to achieve the above object, the inventors found that when mist or droplets containing a raw material for deposition are retained and impregnated into a substrate, a film of good quality can be obtained simply and easily on both sides of the substrate. The inventor also found that when a flow velocity in a direction is given to the mist or droplet after use, a better productivity can be achieved. Furthermore, the inventors found that such a processing apparatus can be applied to surface processing, such as etching, and found that such a processing apparatus can solve the above-mentioned conventional problem.

In addition, after learning the above findings, the inventors have made further research to reach the present invention.

That is, the present invention relates to the followings.

[1] A processing system including an impregnation device that is configured to impregnate a base with mist containing a processing agent under an atmosphere of the mist.
[2] The processing system of [1] above, further including a retaining device that retains the mist.
[3] The processing system of [1] or [2] above, further including a mist discharging device that discharges the mist after use.
[4] The processing system of any one of [1] to [3] above, further including an acceleration device that gives a flow velocity to the mist after use in a direction.
[5] The processing system of any one of [1] to [4] above, further including a conveying device that conveys the base.
[6] The processing system of any one of [1] to [5] above, further including a feeding device that feeds the base.
[7] The processing system of any one of [1] to [6] above, further including a heater.
[8] The processing system of any one of [1] to [7] above, wherein the processing agent includes a raw material for deposition.
[9] The processing system of any one of [1] to [8] above, wherein the processing agent includes an etching agent.
[10] The processing system of any one of [1] to [9] above, wherein the processing agent includes a chemical adsorbent.
[11] The processing system of any one of [1] to [10] above, further including a gas processing device that process the base with a gas.
[12] A processing method, including: impregnating a base with mist containing a processing agent under an atmosphere of the mist.
[13] The processing method of [12] above, further including: retaining the mist; and impregnating the base with the mist that is retained.
[14] The processing method according to [12] or [13] above, further including: discharging the mist after use after the impregnating step.
[15] The processing method according to any one of [12] to [14] above, further including: giving a flow velocity to the mist after use in a direction after the impregnating step.
[16] The processing method according to any one of [12] to [15] above, wherein the impregnating step is conducted in conveying the base.
[17] The processing method according to any one of [12] to [16] above, wherein the impregnating step is conducted after feeding the base in a direction of gravity.
[18] The processing method according to any one of [12] to [17] above, further including: heating the base before or after the impregnating step.
[19] The processing method according to any one of [12] to [18] above, wherein the processing agent includes a raw material for deposition and the processing is a deposition processing.
[20] The processing method according to any one of [12] to [19] above, wherein the processing agent includes an etching agent and the processing is an etching processing.
[21] The processing method according to any one of [12] to [20] above, wherein the processing agent includes a chemical adsorbent and the processing is a chemisorption process.
[22] The processing method according to any one of [12] to [21] above, further including: processing the base with a gas before and/or after the impregnating step.

### Advantageous Effects of Invention

According to what is disclosed in the specification of the present inventive subject matter, it is capable of processing a base industrially advantageously.

### BRIEF DESCRIPTION OF THE DRAWINGS

FIG. 1 is a schematic diagram illustrating an embodiment of the processing apparatus (system) of the present invention.

FIG. 2 is a diagram illustrating an embodiment of an atomizing section (mist generator) used in the present invention.

FIG. 3 is a schematic diagram illustrating an embodiment of a processing apparatus (system) of the present invention.

FIG. 4 is a schematic diagram illustrating an embodiment of a processing apparatus (system) of the present invention.

FIG. 5 is a schematic diagram illustrating an embodiment of a processing apparatus (system) of the present invention.

FIG. 6 is a schematic diagram illustrating an embodiment of a processing apparatus (system) of the present invention.

### DESCRIPTION OF EMBODIMENTS

A processing apparatus of an embodiment of the present inventive subject matter is a processing apparatus that processes a base using mist or droplets containing a processing agent, and includes a retaining section that retains the mist or droplets. The processing apparatus of the embodiment of the present inventive subject matter further includes therein an impregnation means that impregnates the base with the mist or droplets retained in the retaining section. Further, a processing apparatus of an embodiment of the present inventive subject matter is a processing apparatus that processes a base using mist or droplets containing a processing agent, and includes an impregnation section that impregnates the base with the mist or droplet. The processing apparatus of the embodiment of the present inventive subject matter further includes a mist/droplet-acceleration means that gives a flow velocity to the mist or droplet after use in a direction.

A base used in the present inventive subject matter is not particularly limited, and may be a known base. A material of the base is not particularly limited unless it deviates from an object of the present inventive subject matter and the material of the base may be an organic compound or an inorganic compound. A shape of the base may be of any shape and is effective for all forms. Examples of the shape of the base include plate such as flat plate and disk, fibrous, bar, columnar, prismatic, cylindrical, spiral, spherical, annular, and porous. According to an embodiment of the present inventive subject matter, the base is preferably a substrate and more preferably a flexible substrate. A thickness of the substrate is not particularly limited according to the present inventive subject matter, but is preferably in a range of from 1 μm to 100 mm, more preferably in a range of from 10 μm to 10 mm. An area of the substrate is not particularly limited, but is preferably equal to or more than 5 mm square, more preferably equal to or more than 1 cm square, and most preferably equal to or more than 5 cm square.

The substrate is not particularly limited unless it deviates from an object of the present inventive subject matter and may be a known substrate. Examples of the substrate include an insulating substrate, a semiconductor substrate, a metal substrate, and a conductive substrate. Further, according to an embodiment of the present inventive subject matter, a substrate with at least a film selected from among a metal film, a semiconductor film, a conductive film, and an insulating film, on a part or whole surface of the substrate may also be suitably used. Examples of a metal constituting the metal film include one or more metals selected from gallium, iron, indium, aluminum, vanadium, titanium, chromium, rhodium, nickel, cobalt, zinc, magnesium, calcium, silicon, yttrium, strontium, and barium. Examples of a material constituting the semiconductor film include a single substance of an element such as silicon or germanium, a compound containing an element of Groups from 3 to 5 and Groups from 13 to 15 of the periodic table, a metal oxide, a metal sulfide, a metal selenide, a metal nitride, a perovskite. Examples of a material constituting the conductive film include tin-doped indium oxide (ITO), fluorine-doped indium oxide (FTO), zinc oxide (ZnO), aluminum-doped zinc oxide (AZO), gallium-doped zinc oxide (GZO), tin oxide (Sn₀₂), indium oxide (In₂O₃), tungsten oxide (WO₃). Examples of a materials constituting the insulating film include aluminum oxide (Al₂O₃), titanium oxide (TiO₂), silicon oxide (SiO₂), silicon nitride (Si₂N₄), silicon oxynitride (Si₄O₅N₃). According to an embodiment of the present inventive subject matter, the insulating film is preferably made of an insulating oxide, and more preferably a titania film.

A processing agent used in the present inventive subject matter is not particularly limited as long as the processing agent is capable of processing the substrate, and may be a known processing agent. Examples of the processing agent include a raw material for deposition, an etching agent, a surface modifying agent, a cleaning agent, and a rinsing agent. Further, according to an embodiment of the present inventive subject matter, it is preferable that the processing agent is a chemical adsorbent because it enables to impart enhanced orientation properties to the base and to obtain a base that is more suitable for large-area oriented growth.

The raw material for deposition of an embodiment may be a known raw material for deposition unless it deviates from an object of the present inventive subject matter. The raw material for deposition may be an inorganic material or an organic material. According to an embodiment of the present inventive subject matter, the raw material for deposition preferably contains a metal or a metal compound, more preferably contains one or more metals selected from gallium, iron, indium, aluminum, vanadium, titanium, chromium, rhodium, nickel, cobalt, zinc, magnesium, calcium, yttrium, strontium, barium, and silicon, and most preferably contains a silicon-containing compound. The silicon-containing compound is not particularly limited as long as the silicon-containing compound contains at least one silicon atom. Examples of the silicon-containing compound include silane, siloxane, silazane and polysilazane. Examples of the silane include monosilane (SiH₄), alkoxysilane. Examples of the alkoxysilane include tetraethoxysilane (TEOS), tetramethoxysilane, tetrapropoxysilane, tetrabutoxysilane, tetraamyloxysilane, tetraoctyloxysilane, tetranonyloxysilane, dimethoxydiethoxysilane, dimethoxydiisopropoxysilane, diethoxydiisopropoxysilane, diethoxydibutoxysilane, diethoxyditrityloxysilane, and mixtures thereof. Examples of the siloxane include hexamethyldisiloxane, 1,3-dibutyltetramethyldisiloxane, 1,3-diphenyltetramethyldisiloxane, 1,3-divinyltetramethyldi siloxane, hexaethyldisiloxane and 3-glycidoxypropylpentamethyldi siloxane. Examples of the silazane include hexamethyldisilazane and hexaethyldisilazane. According to an embodiment of the present inventive subject matter, it is also preferable that the raw material for deposition contains a metal in the form of a complex or a salt. Examples of the form of the complex include organic complexes, and more specifically, acetylacetonato complexes, carbonyl complexes, ammine complexes, hydride complexes, and quinolinol complexes. Examples of the salt form include a halide, and more specifically, a metal chloride salt, a metal bromide salt, and a metal iodide salt.

The etching agent is not particularly limited unless it deviates from an object of the present inventive subject matter, and may be a known etching agent. Examples of the etching agent include organic acids (e.g., sulfuric acid, nitric acid, hydrochloric acid, acetic acid, formic acid, fluoric acid), oxidizing agents (e.g., hydrogen peroxide, concentrated sulfuric acid), chelating agents (e.g., iminodiacetic acid, nitrilotriacetic acid, ethylenediamine tetraacetic acid, ethylenediamine, ethanolamine, aminopropanol), thiol compounds. The etching agent may also include, for example, imidazole, an imidazole derivative compound that has an etching action by itself.

The surface modifier is not particularly limited unless it deviates from an object of the present inventive subject matter, and may be a known surface modifier. Examples of the surface modifier include anion-based and cation-based surfactants, nonion-based surfactants, amphoteric surfactants, polymer surfactants, pigment dispersants, alcohols, fatty acids, amines, amides, imides, metal soaps, fatty acid oligomer compounds, silane coupling agent, thitanate coupling agent, aluminate coupling agent, phosphate coupling agent, carboxylic acid coupling agent, fluoroactive surfactants, and boron-based surfactants. A raw material solution may contain one type of the surface modifying agent alone or contain two or more types of the surface modifying agents.

The chemical adsorbent is not particularly limited and may be a known chemical adsorbent. According to an embodiment of the present inventive subject matter, it is preferable that the chemical adsorbent is a self-assembled monolayer (SAM) forming material. The SAM forming material is not particularly limited, and may be a known SAM forming material. Examples of the SAM forming material include a thiol compound, a silane compound, an organophosphorus compound, and a carboxylic acid compound.

The cleaning agent is not particularly limited unless it deviates from an object of the present inventive subject matter is not interfered with, and may be a known cleaning agent. Examples of the cleaning agent include a surfactant, such as an anionic surfactant and a nonionic surfactant, and a metal soap.

The rinsing agent is not particularly limited unless it deviates from an object of the present inventive subject matter, and may be a known rinsing agent. Examples of the rinsing agent include fluorine-based rinsing agents such as a hydrofluorocarbon (HFC) and hydrofluoroether (HFE).

According to an embodiment of the present inventive subject matter, it is preferable that the processing apparatus further includes a mist generator such as an atomizing section or a droplets-forming section. The processing apparatus including the mist generator is capable of atomizing or forming droplets a processing solution in which the processing agent is dissolved or dispersed in, for example, the solvent. The mist generated by atomizing or forming droplets the processing solution may contain droplets. The mist generator such as an atomizing section or a droplets-forming section is capable of controlling a quality of the processing agent more easily. The mist generator is also capable of improving an efficiency and quality of the processing itself.

The solvent is not particularly limited if the processing agent is dissolved or dispersed and if the processing agent can be atomized or formed into droplets. The solvent may be an inorganic solvent, an organic solvent, and a mixed solvent thereof. According to an embodiment of the present inventive subject matter, it is preferable that the solvent is water.

An amount of a content of the processing agent in the processing solution is not particularly limited. The content of the processing agent in the processing solution is preferably from 0.0001 to 80% by weight, more preferably from 0.001% to 50% by weight, for example.

According to an embodiment of the present inventive subject matter, the mist is preferably obtained by using ultrasonic vibration. This is because the mist obtained by using ultrasonic vibration is easy to be retained. The mist obtained by using ultrasonic vibration has an initial velocity that is zero and floats in the space. The mist floating in the space, that is carriable as a gas is preferable to avoid damage caused by a collision energy without being, for example, blown like a spray. The mist may include droplets. A diameter of the mist is not particularly limited, and may be approximately several mm. The diameter of the mist is preferably equal to 50 μm or less, more preferably from 1 μm to 10 μm. When the processing solution is atomized by means other than ultrasonic vibration, generally, a retaining means that can stop a movement of the mist may be used.

According to an embodiment of the present inventive subject matter, it is preferable that the atomizing section or the droplets-forming section has an atomizing tank, and the retaining section is in the atomizing tank. This configuration enables to more easily solve, for example, the problems caused by idling of a vacuum processing apparatus.

According to an embodiment of the present inventive subject matter, it is preferable that the impregnation section includes a feeding means that feeds the base in a direction of gravity or substantially in a direction of gravity, and is configured to impregnate the base with the mist or droplets after feeding. This configuration enables to process the base more efficiently and in a larger amount.

According to an embodiment of the present inventive subject matter, it is preferable that the processing apparatus further includes a heating means. This configuration is capable of subjecting the mist, that is stable and having a long disappearance time, into the processing.

Further, according to an embodiment of the present inventive subject matter, the processing apparatus preferably includes a gas processing means configured to process the base with a gas. This configuration is capable of processing the base more effectively and efficiently.

Further, according to an embodiment of the present inventive subject matter, it is preferable that the processing apparatus further includes a mist flow velocity giving means that gives a flow velocity in a direction to the mist after use. By giving a flow velocity to the mist after use, the mist after use may be more efficiently discharged and the unused mist may be more efficiently subjected to processing.

A processing system according to an embodiment of the present inventive subject matter includes an impregnation device that impregnates the base with the mist under an atmosphere of the mist containing a processing agent. A processing system according to another embodiment of the present inventive subject matter includes a flow velocity giving device that gives a flow velocity to the mist after use.

The impregnation device is not particularly limited as long as the impregnation device includes the impregnation section. The impregnation device may be the same as the impregnation section. According to an embodiment of the present inventive subject matter, it is preferable that the impregnation device includes a retaining device that retains the mist and is configured to impregnate the base with the mist inside in the retaining device. The retaining device is not particularly limited as long as the retaining device includes a retaining section. The retaining device may be the same as the retaining section.

According to an embodiment of the present inventive subject matter, it is preferable that the processing system also includes a mist-discharging device that discharges the mist after use. This is because the mist after use may be discharged more efficiently and the unused mist may be processed more efficiently. The mist-discharging device is not particularly limited as long as the mist-discharging device can discharge the mist after use. Further, the acceleration device is not particularly limited as long as the acceleration device includes the flow velocity giving means. According to an embodiment of the present inventive subject matter, it is also preferable that the acceleration device is the mist-discharging device.

According to an embodiment of the present inventive subject matter, it is preferable that the processing system further includes a heater because a stable mist having a long time to disappear can be processed. The heater is not particularly limited as long as the heater includes the heating means.

According to an embodiment of the present inventive subject matter, it is preferable that the impregnation device includes a conveying device that conveys the base, and is configured to impregnate the base with the mist while conveying the base. This configuration enables to process the base more efficiently and more extensively. The conveying device is not particularly limited as long as the conveying device can convey the base. According to an embodiment of the present inventive subject matter, it is also preferable that the conveying device is a feeding device that feeds the base, and is configured to impregnate the base with the mist after feeding the base in the direction of gravity. The feeding device is not particularly limited as long as the feeding device includes a feeding means.

In addition, according to an embodiment of the present inventive subject matter, it is preferable that the processing system includes a gas processing device that processes the base with a gas. This configuration enables to process more effectively and efficiently. The gas processing device is not particularly limited as long as the gas processing device includes a gas processing means. The gas processing includes, for example, replacing gas inside the retaining device.

Hereinafter, embodiments of the present inventive subject matter will be described with reference to the drawings.

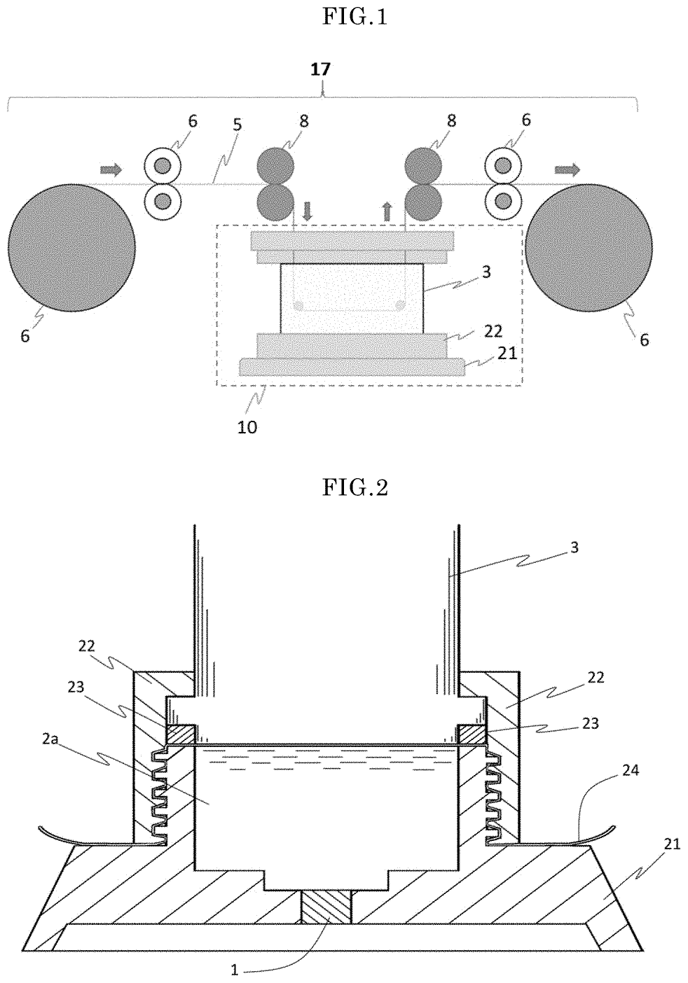

The processing apparatus (system) of FIG. 1 includes a feeding roller (feeding device) 6, a heating roller (heater) 8, and a retaining section (retaining device) 10. A mist (not shown) is retained in the retaining section (retaining device) 10, and a base 5 is conveyed in the feeding direction by the feeding roller (feeding device) 6 to be impregnated in the retaining section (retaining device) 10. In the processing apparatus (system) of FIG. 1, an impregnation section (impregnation device) 17 refers to a configuration including the retaining section (retaining device) 10, the feeding roller (feeding device) 6, and the base 5. Before the impregnation processing, the base 5 is heated by the heating roller 8. After the impregnation processing, the processed base is conveyed in the feeding direction by the feeding roller (feeding device) 6, and the processed base 5 is further heated by the heating roller (heater) 8 after the impregnation processing. According to an embodiment of the present inventive subject matter, it is also preferable that the impregnation processing is conducted while the substrate 5 is conveyed by a feeding roller 6. According to an embodiment of the present inventive subject matter, it is also preferable that the impregnation processing is performed after the substrate 5 is conveyed in the feeding direction by the feeding roller (feeding device) 6.

FIG. 2 shows an embodiment of an atomizing section (a mist generator) used in the present inventive subject matter. The atomizing section (mist generator) described in FIG. 2 shows a cross section of an ultrasonic vibrator 1, a support portion 21, a fixing nut 22, an O-ring 23, a polymer film 24, and a cylindrical body 3, respectively. The cylindrical body 3 is a container for accommodating a processing solution. A convex portion provided at a lower portion of the cylindrical body 3 is fitted between the fixing nut 22 and the support portion 21 via the O-ring 23 and the polymer film 24. The fixing nut 22 and the support portion 21 are screwed together, and by this screwing together, the polymer film 24 closes a bottom surface portion of the cylindrical body 3 to form the bottom surface of the cylindrical body 3. In addition, an installation hole for the ultrasonic vibrator 1 is provided in a bottom surface portion of the support portion 21, and the ultrasonic vibrator 1 is installed in the installation hole via a vibrator fixing tool so as to be able to irradiate ultrasonic waves to the bottom surface portion of the cylindrical body 3. In addition, water is accommodated as an ultrasonic propagation liquid 2a between the bottom surface portion of the cylindrical body 3 and the support portion 21. The cylindrical body 3 contains a processing solution that is not shown. Although the polymer film 24 is disposed under the O-ring 23 in FIG. 2, the polymer film 24 may be disposed on the O-ring 23 in an embodiment of the present inventive subject matter. Then, by operating the ultrasonic vibrator 1 disposed in the installation hole provided in the bottom surface portion of the support portion 21, the ultrasonic vibration is propagated to the processing solution in the cylindrical body 3 via the ultrasonic propagation liquid 2a. When the processing solution irradiated with the ultrasonic wave is atomized, the obtained mist stays in the cylindrical body 3.

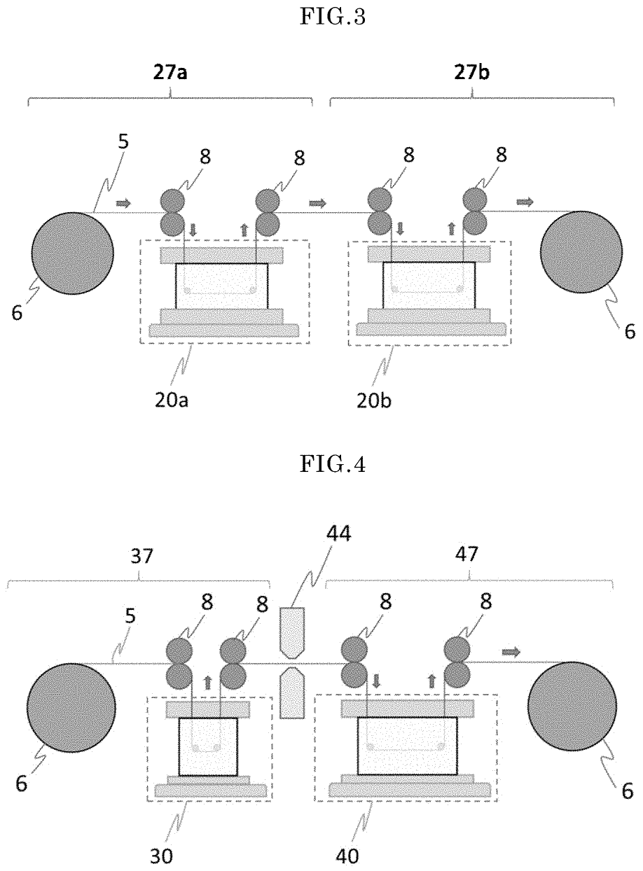

FIG. 3 shows a processing apparatus (system) according to an embodiment of the present inventive subject matter, having two retaining sections (retaining devices). According to the embodiment of the present inventive subject matter, it is preferable that two or more retaining sections (retaining devices) are provided, and each of the two or more retaining sections (retaining devices) respectively include two or more impregnation sections (impregnation devices). Thus, even when a mist is used, a plurality of processes would be performed more effectively and efficiently. In FIG. 3, a first impregnation processing is performed in a retaining sections (retaining device) 20a, and a second impregnation processing is performed in a retaining section (retaining device) 20b. Note that the first impregnation processing and the second impregnation processing may be the same processing or may be different processing. For example, after a deposition process is performed by impregnating a base with mist containing a first raw material for deposition in the first retaining section (retaining device) 20a, a deposition process may be performed by impregnating a base with mist containing a second raw material for deposition that is different from the first raw material for deposition in the second retaining section (retaining device) 20b. In addition, for example, after a cleaning process is performed by impregnating a base with mist containing a cleaning agent in the first retaining section (retaining device) 20a, and then a deposition process may be performed by impregnating the base with mist containing a raw material for deposition in the retaining section (retaining device) 20b. In the processing apparatus (system) of FIG. 3, an impregnation section (impregnation device) 27a or an impregnation section (impregnation device) 27b respectively refer to a configuration including the first retaining section (retaining device) 20a or the second retaining section (retaining device) 20b, the feeding roller (feeding device) 6, and the base 5.

Although FIG. 3 exemplifies the processing apparatus (system) including two retaining sections (retaining devices), the present inventive subject matter is not limited to the two retaining sections (retaining devices), but may include three or more retaining sections (retaining devices). According to an embodiment of the present inventive subject matter, three or more impregnation processing may be performed.

A processing apparatus (system) of FIG. 4 differs from the processing apparatus (system) of FIG. 3 in that two retaining sections (retaining devices) are different in size. In FIG. 4, a processing time of an impregnation processing is adjusted by designing each size of retaining sections different from each other. The processing apparatus (system) of FIG. 4 includes a plasma processing section (plasma processing device). After an impregnation processing in a retaining section (retaining device) 30, a plasma processing may be performed in a plasma processing section (plasma processing device) 44. Then, an impregnation processing may be performed immediately in a retaining section 40. In the processing apparatus (system) of FIG. 4, the impregnation section (impregnation device) 37 or the impregnation section (impregnation device) 47 respectively refer to a configuration including the retaining section (retaining device) 30 or the retaining section (retaining device) 40, the feeding roller (feeding device) 6, and the base 5.

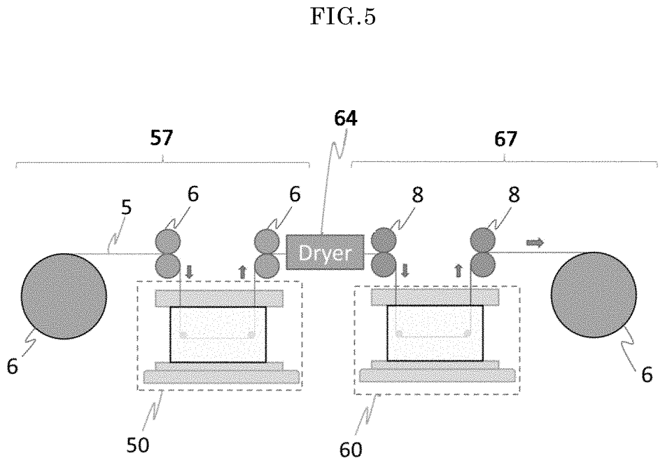

In a processing apparatus (system) of FIG. 5, a heating roller (heater) 8 is provided so that only a retaining section (retaining device) 60 can have a heat processing before and after an impregnation processing. The processing apparatus (system) of FIG. 5 includes a drying section (drying device) 64, and is configured to dry a base after the impregnation process in a retaining section (retaining device) 50. After the drying processing, the base is heated by the heating roller (heater) 8, then impregnated by the retaining section (staying device) 60, and then sent out to the heating roller (heater) 8. In the processing apparatus (system) of FIG. 5, a impregnation section (impregnation device) 57 or a impregnation section (impregnation device) 67 respectively refer to a configuration including the retaining section (retaining device) 50 or the retaining section (retaining device) 60, a feeding roller (feeding device) 6, and the base 5.

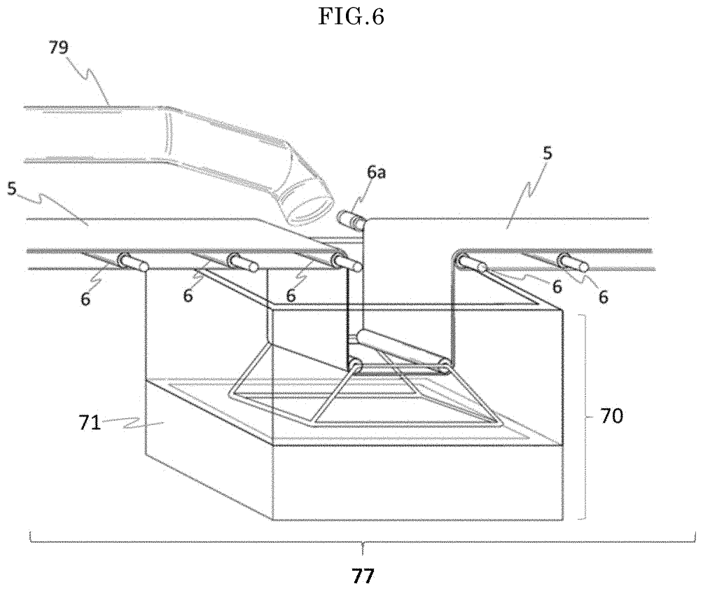

Another embodiment of the present inventive subject matter is shown in FIG. 6. A processing apparatus (system) of FIG. 6 includes a plurality of feeding rollers (feed devices) 6 including a drive section (drive device) 6a, a retaining section (retaining device) 70, an atomizing section (mist generator) 71, and a mist discharging section (mist discharging device) 79. The mist discharging section 79 is configured to be able to intake and discharge the mist after use. The processing apparatus (system) of FIG. 6 is configured to give a flow velocity in a direction by the mist-discharging section (mist-discharging device) 79 to the mist after use after the impregnation. After the base 5 is impregnated in the retaining section (retaining device) 70, the mist after use is discharged by the mist discharging section (mist discharging device) 79. According to an embodiment of the present inventive subject matter, a gas processing device may be configured to send out a gas, such as nitrogen gas instead of the mist-discharging section (mist-discharging device) 79. In such a case, the inside of the retaining section (retaining device) 70 may be replaced with a gas, or the base may be processed with a gas. In the processing apparatus (system) of FIG. 6, the impregnation section (impregnation device) 77 refers to a configuration including the retaining section (retaining device) 70, the feeding roller (feeding device) 6, and the base 5.

### INDUSTRIAL APPLICABILITY

The processing apparatus and the processing method of the present inventive subject matter may be used to process any kinds of bases and be industrially useful. In particular, in the case of deposition or performing an etching processing on the base surface, the processing apparatus and the processing method of the present inventive subject matter may be suitably applied.

### REFERENCE NUMBER DESCRIPTION

1 Ultrasonic vibrator
2 Ultrapure water
3 Cylindrical body
4 Base
6 Feeding roller (Feeding device)
6a Drive section (drive device)
8 Heating roller (heater)
10 Retaining section (Retaining device)
17 Impregnation section (Impregnation device)
20a Retaining section (Retaining device)
20b Retaining section (Retaining device)
21 Support portion
22 Fixing nut
23 O-ring
24 Polymer film
27a Impregnation section (impregnation device)
27b Impregnation section (impregnation device)
30 Retaining section (Retaining device)
37 Impregnation section (Impregnation device)
40 Retaining section (Retaining device)
47 Impregnation section (Impregnation device)
44 Plasma processing section (Plasma processing device)
50 Retaining section (Retaining device)
57 Impregnation section (Impregnation device)
60 Retaining section (Retaining device)
67 Impregnation section (Impregnation device)
64 Drying section (Drying device)
70 Retaining section (Retaining device)
71 Atomizing section (Mist generator)
77 Impregnation section (Impregnation device)
79 Mist-discharging section (Mist-discharging device)

1. A processing system comprising:
an impregnation device that is configured to impregnate a base with mist containing a processing agent under an atmosphere of the mist.

2. The processing system of claim 1, further comprising a retaining device that retains the mist.

3. The processing system of claim 1, further comprising a mist discharging device that discharges the mist after use.

4. The processing system of claim 1, further comprising an acceleration device that gives a flow velocity to the mist after use in a direction.

5. The processing system of claim 1, further comprising a conveying device that conveys the base.

6. The processing system of claim 1, further comprising a feeding device that feeds the base.

7. The processing system of claim 1, further comprising a heater.

8. The processing system of claim 1, wherein the processing agent comprises a raw material for deposition.

9. The processing system of claim 1, wherein the processing agent comprises an etching agent.

10. The processing system of claim 1, wherein the processing agent comprises a chemical adsorbent.

11. The processing system of claim 1, further comprising a gas processing device that process the base with a gas.

12. A processing method, comprising:
impregnating a base with mist containing a processing agent under an atmosphere of the mist.

13. The processing method of claim 12, further comprising:
retaining the mist; and
impregnating the base with the mist that is retained.

14. The processing method according to claim 12, further comprising:
discharging the mist after use after the impregnating step.

15. The processing method according to claim 12, further comprising:
giving a flow velocity to the mist after use in a direction after the impregnating step.

16. The processing method according to claim 12,
wherein the impregnating step is conducted in conveying the base.

17. The processing method according to claim 12,
wherein the impregnating step is conducted after feeding the base in a direction of gravity.

18. The processing method according to claim 12, further comprising:
heating the base before or after the impregnating step.

19. The processing method according to claim 12,
wherein the processing agent comprises a raw material for deposition and the processing is a deposition processing.

20. The processing method according to claim 12,
wherein the processing agent comprises an etching agent and the processing is an etching processing.

21. The processing method according to claim 12,
wherein the processing agent comprises a chemical adsorbent and the processing is a chemisorption process.

22. The processing method according to claim 12, further comprising:
processing the base with a gas before and/or after the impregnating step.
